(19) United States
(12) Patent Application Publication
(10) Pub. No.: US 2011/0192348 A1
(43) Pub. Date: Aug. 11, 2011

(54) RF Hollow Cathode Plasma Generator

(75) Inventors: Ching-Pei Tseng, Taoyuan County (TW); Cheng-Chang Hsieh, Taoyuan County (TW); Chi-Fong Ai, Taoyuan County (TW); Chia-Cheng Lee, Taoyuan County (TW); Deng-Lain Lin, Taoyuan County (TW)

(73) Assignee: ATOMIC ENERGY COUNCIL-INSTITUTE OF NUCLEAR ENERGY RESEARCH, Taoyuan County (TW)

(21) Appl. No.: 12/701,035

(22) Filed: Feb. 5, 2010

(51) Int. Cl. C23C 16/00; H05H 1/24

(52) U.S. Cl. 118/723 E; 313/231.31; 315/111.21

(57) ABSTRACT

An RF hollow cathode plasma source consists of a vacuum chamber, a pipe, a hollow cathode, at least two compartments, a conduit and input electrodes. The pipe is inserted into the chamber for introducing working gas into the chamber. The hollow cathode is disposed in the chamber and formed with a large number of apertures. At least two compartments are located below the hollow cathode. Each of the compartments includes small apertures for uniformly spreading the working gas into the apertures of the hollow cathode. The conduit is disposed along two sides of the hollow cathode to circulate cooling water around the hollow cathode. The plural input power leads are arranged near the hollow cathode. The input power leads, the pipe and the conduits are connected to the hollow cathode though the electrically-insulated walls of the grounded vacuum chamber.

### FIELD OF THE INVENTION

The present invention relates to a radio frequency (“RF”) hollow cathode plasma source.

### DESCRIPTION OF THE RELATED ARTS

A typical plasma source consists of a pair of planar electrodes disposed in a vacuum chamber. Working gas such as argon or oxygen is introduced into the chamber after it is evacuated to the required vacuum condition. The pressure is about 10˜10⁻² torr in the chamber during operation.

A DC or pulsed DC electric power may be applied to the pair of planar electrode to generate a negative voltage and therefore an electric field. Accelerating to high energy by the electric field, electrons bombard and ionize the neutral working gas. Thus, plasma is generated.

Alternatively, an RF (Radio frequency) electric power may be applied to the pair of planar electrodes to generate an alternating electric field. Accelerating to high energy by the alternating electric field, electrons hit and ionize the working gas. Thus, RF plasma is generated.

The plasma is an ionized gas plus the Debye shielding effect of the electrodes due to the applied electric power. The electric field decreases exponentially as it goes further from the electrode, thus forming a plasma sheath. The plasma spreads over the electrode and diffuses outward. The electrons are accelerated and gain energy because of the electric field in the plasma sheath in the vacuum chamber. The high-energy electrons bombard various particles and ionize molecules of the working gas. Thus, more and more ion-electron mixture is generated to maintain the plasma condition. The plasma spreads widely in space so that its density thereof is low. Therefore, the application of the plasma is not efficient.

A hollow cathode plasma source includes an electrode made with numerous apertures. Positive ions and high-energy secondary electrons hit the walls of the apertures and bounce back and forth. They make many collisions with the molecules of the working gas and ionize them and generate more secondary electrons. Thus, high-density plasma is more easily generated due to the greatly enhanced probability of electron bombardment in the apertures. The uniformity of the plasma is significantly affected by the distribution of the working gas in the hollow cathode. To ensure identical flow rates of various gas pipes, apertures with different diameters are made in a small pipe because of their different pressures, or apertures with same diameter are made in a large pipe due to their same pressures.

As disclosed in U.S. Pat. No. 4,767,641, a power supply energizes a hollow cathode in a chamber. The profile of the hollow cathode may be square, hexagonal or rectangular.

As disclosed in Taiwanese Patent Publication No. 259506, “Control over Evenness of Plasma by Design of Gas-Distributing Apertures”, an RF power supply is used to generate high-density plasma, in which the shapes and positions of apertures are used to increase the uniformity of the working gas. However, their shapes and positions of the apertures have to be designed according to specific electrode configuration. The design would not be possible without a thorough study of the flow field of the working gas.

As discussed, an RF power supply can be used to generate plasma but it is difficult to uniformly distribute their working gases and spread the plasma in one single direction. Therefore, the present invention is intended to obviate or at least alleviate the problems encountered in prior art.

### SUMMARY OF THE INVENTION

It is an objective of the present invention to provide an RF hollow cathode plasma source that can be used together with a power supply operated at various frequencies.

It is another objective of the present invention to provide an RF hollow cathode plasma source that can generate high density plasma with excellent uniformity in its distribution of working gas.

It is another objective of the present invention to provide an RF hollow cathode plasma source for use in the plasma-based activation of polymers, plasma-enhanced chemical vapor deposition and other plasma surface modification so as to increase its treatment rate and uniformity.

To achieve the foregoing objectives, the RF hollow cathode plasma source includes a vacuum chamber, a gas pipe, a hollow cathode, at least two gas compartments, two conduits for cooling water and plural input power leads. The gas pipe is inserted into the chamber for introducing working gas into the chamber. The hollow cathode is disposed in the chamber and is formed with numerous apertures. Each aperture is further disposed with a mall aperture for gas entrance at its bottom. At least two gas compartments are located below the hollow cathode. Each of the compartments includes numerous small apertures for uniformly spreading the working gas into the apertures of the hollow cathode. The conduit is arranged around the hollow cathode to circulate cooling water around the hollow cathode. The input power leads are arranged near the hollow cathode. The input power leads, the gas pipe and the conduit are connected to the hollow cathode through the wall of the vacuum chamber for input power connection.

Other objectives, advantages and features of the present invention will become apparent from the following description referring to the attached drawings.

### BRIEF DESCRIPTIONS OF THE DRAWINGS

The present invention will be described via the detailed illustration of the preferred embodiment referring to the drawings.

FIG. 1 is a cross-sectional view of an RF hollow cathode plasma source according to the preferred embodiment of the present invention.

FIG. 2 is a top view of the RF hollow cathode plasma source shown in FIG. 1.

FIG. 3 is a side view of the RF hollow cathode plasma source shown in FIG. 1.

### DESCRIPTION OF THE PREFERRED EMBODIMENT

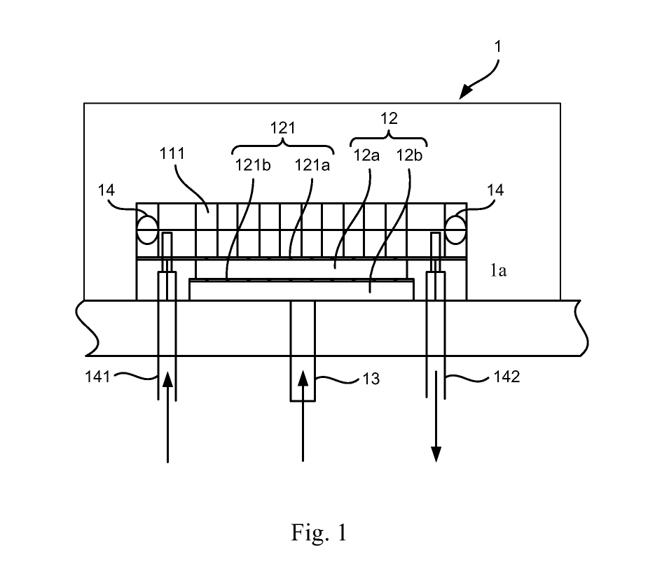

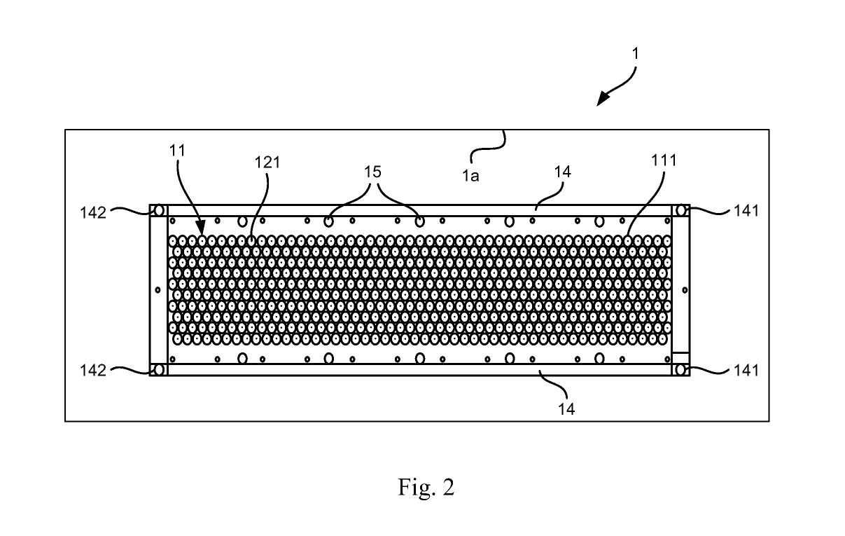

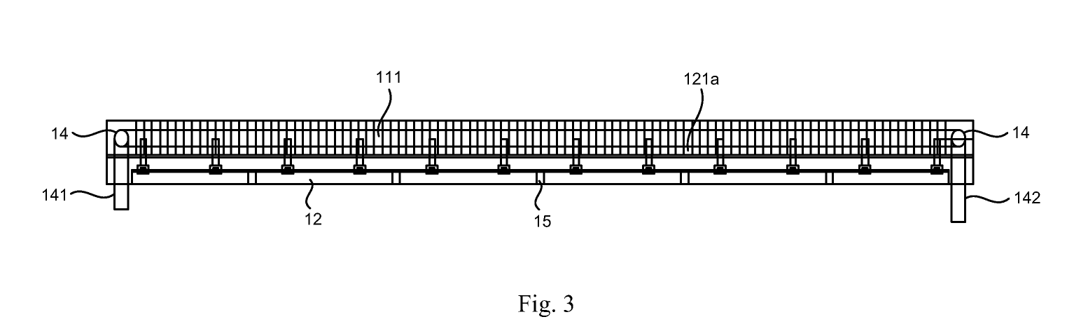

Referring to FIGS. 1 through 3, an RF hollow cathode plasma source includes a vacuum chamber 1a, a hollow cathode 11, at least two gas compartments 12, a gas pipe 13, a conduit and input power leads 15 according to the preferred embodiment of the present invention.

The hollow cathode 11 is disposed in the chamber 1a and electrically insulated from it. The hollow cathode 11 consists of a large number of apertures 111, in which there is a small gas entrance aperture 121a in the bottom of each aperture. Two conduits 14 are disposed along two sides of the hollow cathode 11. Two ends of each conduit are connected respectively with an entrance tube 141 and an exit tube 142.

The gas compartments 12a and 12b are parts of the hollow cathode 11 and are overlapped and located below the hollow cathode 11 within the chamber 1a. Each of the compartments 12a and 12b includes small apertures 121a and 121b, respectively. Each of the small apertures 121a and 121b is aligned with its related apertures 111 of the hollow cathode 11 so that the working gas is uniformly transferred into the apertures 111 of the hollow cathode 11 from the compartments 12 and is evenly spread in the hollow cathode 11. Accordingly, the plasma and free radicals are evenly spread.

The gas pipe 13 is inserted into the chamber 1a. The pipe 13 is used to transfer the working gas into the compartments 12b.

Two conduits 14 are disposed along two sides of the hollow cathode 11. Two ends of each conduit 14 are connected respectively to the entrance tube 141 and the exit tube 142 of cooling water. Thus, cooling water circulates from the entrance tube 141 through conduit 14 to the exit tube 142 to cool the hollow cathode 11.

The input power leads 15 are located near hollow cathode 11. The input power leads 15, the pipe 13 and the conduits 14 are electrically connected to the hollow cathode 11 through the electrically-insulated walls of the vacuum chamber 1a.

Two compartments 12 or more are included based on the flow field of the working gas so as to achieve the uniform distribution of working gas. Furthermore, The entrance tube 141 and the exit tube 142 are parts of the hollow cathode 11 and the input power leads 15 are located near the hollow cathode 11 and are uniformly distributed around the hollow cathode 11 so that the input electric power is uniformly distributed over the hollow cathode 11. Accordingly, the plasma and free radicals are uniformly distributed over the hollow cathode.

The RF hollow cathode plasma source is driven by an RF power supply operated at 1 to 300 MHz to energize the hollow cathode 11 to generate the plasma.

The reactive gas is introduced into the vacuum chamber 1a through an input defined in the chamber. The reactive gas is transferred into the first compartment 12b through the pipe 13 so that there is substantially a same pressure in the first compartment 12b. Then, the reactive gas is evenly transferred into the second compartment 12a from the first compartment 12b through the small apertures 121b of the first compartment 12b. Then, the working gas is evenly transferred into the apertures 111 of the hollow cathode 11 from the second compartment 12a through the small apertures 121a of the second compartment 12a. Thus, the plasma is uniformly generated in the apertures 111 of the hollow cathode 11 when the RF power supply is turned on. The generated plasma is blown out of the apertures 111 of the hollow cathode 11 by the reactive gas in one single direction onto a workpiece located near the hollow cathode 11 so as to accomplish plasma treatment and depositions.

The cooling water is transferred into the conduits 14 via the entrance tube 141 and then transferred through the conduit 14 to the exit tube 142. Thus, the cooling water circulates in the entrance tube 141, the conduit 14 and the exit tube 142 to cool the hollow cathode 11. Therefore, the RF power supply can be operated at a high power to generate the plasma at high density without the risk of overheating. Furthermore, the hollow cathode 11 with apertures 111 is also efficient for increasing the chances of the electron bombardment on the molecules of the working gas for increasing the density of the plasma. Therefore, the deposition efficiency of the workpiece is significantly increased.

In summary, the RF hollow cathode plasma source exhibits advantageous features. Firstly, there are at least two gas compartments 12 for uniformly spreading the working gas over the hollow cathode 11 so that a uniform distribution of the working gas over the RF hollow cathode plasma source can be obtained. Secondly, there are plural input power leads 15 of the hollow cathode 11 for reducing the effects of standing waves and the interference of discharges with one another. Therefore, the RF hollow cathode plasma source can be operated at various RF frequency and the density and uniformity of the plasma are greatly improved. Thirdly, the conduits 14, the entrance tube 141 and the exit tube 142 enable the high flow rate of the cooling water so that the RF hollow cathode plasma source can be operated at a high power for a long time. Therefore, the RF hollow cathode plasma source can be used more efficiently in the plasma-based activation of polymers and plasma-enhanced chemical vapor deposition.

The present invention has been described via the detailed illustration of the preferred embodiment. Those skilled in the art can derive variations from the preferred embodiment without departing from the scope of the present invention. Therefore, the preferred embodiment shall not limit the scope of the present invention defined in the claims.

1. An RF hollow cathode plasma source comprising:
a grounded vacuum chamber;
a gas pipe inserted into the chamber for introducing working gas into the chamber;
a hollow cathode disposed in the chamber and formed with a large number of apertures;
at least two gas compartments located below the hollow cathode and each formed with small apertures for uniformly spreading the working gas into the apertures of the hollow cathode;
two conduits disposed along two sides of the hollow cathode to circulate cooling water around the hollow cathode; and
plural input power leads located near the hollow cathode, wherein the input power leads, the pipe and the conduits are connected to the hollow cathode though the electrically-insulated walls of the vacuum chamber.

2. The RF cathode plasma source according to claim 1, wherein each of the small apertures of each of the compartments is aligned with its related apertures of the hollow cathode.

3. The RF cathode plasma source according to claim 1, wherein the hollow cathode comprises two conduits with two ends connected respectively to an entrance tube and an exit tube so that the cooling water enters the conduit from the entrance tube and leaves the conduit from the exit tube.

4. The RF cathode plasma source according to claim 1, wherein the working gas is firstly guided into one of the gas compartment by a gas pipe and then leaked into another gas compartment via a small gas hole.

5. The RF cathode plasma source according to claim 1, wherein the generated plasma is blown out of the aperture of the hollow cathode by the working gas onto the workpiece in one single direction.

6. The RF cathode plasma source according to claim 1, wherein the RF cathode plasma source is used in plasma-enhanced chemical vapor deposition.
